(19) United States
(12) Patent Application Publication
(10) Pub. No.: US 2019/0006290 A1
(43) Pub. Date: Jan. 3, 2019

(54) SEMICONDUCTOR PACKAGE AND SEMICONDUCTOR PACKAGE MANUFACTURING METHOD

(71) Applicant: DISCO CORPORATION, Tokyo (JP)

(72) Inventors: Byeongdeck Jang, Tokyo (JP); Youngsuk Kim, Tokyo (JP)

(21) Appl. No.: 16/020,073

(22) Filed: Jun. 27, 2018

(30) Foreign Application Priority Data
Jun. 28, 2017 (JP) 2017-126049

(51) Int. Cl. H01L 23/552; H01L 23/528

(52) U.S. Cl. CPC H01L 23/552; H01L 23/5286

(57) ABSTRACT

Disclosed herein is a semiconductor package including a redistribution layer and a semiconductor chip connected to the redistribution layer, the semiconductor chip being sealed with a resin layer, the redistribution layer including a ground line exposed to the side surface of the redistribution layer. The semiconductor package includes a contact metal formed on the side surface of the redistribution layer so as to cover the ground line and a shield layer formed on the upper surface and the side surface of the semiconductor package so as to cover the contact metal. The shield layer is connected through the contact metal to the ground line exposed to the side surface of the redistribution layer.

### BACKGROUND OF THE INVENTION

### Field of the Invention

The present invention relates to a semiconductor package having a shielding function and a manufacturing method for such a semiconductor package.

### Description of the Related Art

In general, a semiconductor package for use in portable communications equipment such as mobile phones is required to suppress the leakage of electromagnetic noise from the semiconductor package, so as to prevent any adverse effect on communications characteristics. As an example of the semiconductor package, there is a configuration such that a semiconductor chip mounted on a distribution layer (wiring layer) is sealed with resin (sealing agent) to form a resin layer, and a shield layer is formed on the outer surface of the resin layer (see Japanese Patent Laid-Open No. 2012-039104, for example). There is a case that the shield layer is formed from a sheet metal. However, since the sheet metal has a large thickness, it causes an interference with a reduction in size and thickness of equipment. To cope with this problem, there has been proposed a technique of forming a thin shield layer by sputtering, spray coating, chemical vapor deposition (CVD), ink jet printing, or screen printing, for example.

### SUMMARY OF THE INVENTION

In recent years, there has been developed a semiconductor package such that wiring is drawn from a semiconductor chip to the lower surface of a semiconductor package to form a thin redistribution layer. To remove the electromagnetic noise from the semiconductor package, a shield layer formed on the side surface of the semiconductor package is connected to a ground line in the redistribution layer. However, since the redistribution layer is thin, there is a possibility that a contact failure may occur between the shield layer and the ground line. To cope with this problem, it may be considered to form a thick post electrode in the semiconductor package and draw a thick line from the post electrode to the side surface of the semiconductor package, whereby the ground line is reliably connected through the post electrode to the shield layer on the side surface of the semiconductor package. However, this configuration causes an increase in manufacturing cost.

It is therefore an object of the present invention to provide a semiconductor package which can make a reliable contact between the ground line in the redistribution layer and the shield layer formed on the side surface of the semiconductor package, without an increase in cost.

It is another object of the present invention to provide a manufacturing method for such a semiconductor package.

In accordance with an aspect of the present invention, there is provided a semiconductor package including a redistribution layer and a chip connected to the redistribution layer, the chip being sealed with a sealing layer, the redistribution layer including a ground line exposed to a side surface of the redistribution layer, the semiconductor package including: a contact metal formed on the side surface of the redistribution layer so as to cover at least the ground line; and a shield layer formed on an exposed surface of the contact metal and an exposed surface of the sealing layer, the shield layer being connected through the contact metal to the ground line exposed to the side surface of the redistribution layer.

With this configuration, the contact metal is formed so as to cover at least the ground line exposed to the side surface of the redistribution layer having a small thickness. Accordingly, a contact area between the contact metal and the shield layer can be increased to thereby ensure the connection between the ground line and the shield layer on the side surface of the semiconductor package. Further, with the simple configuration that the contact metal is formed bn the side surface of the redistribution layer, an increase in cost can be suppressed as compared with the conventional configuration that a post electrode is formed in a semiconductor package.

In accordance with another aspect of the present invention, there is provided a semiconductor package manufacturing method including a preparing step of preparing a package substrate formed by collectively sealing a plurality of chips with a sealing layer, the package substrate including a redistribution layer partitioned by a plurality of crossing division lines to define a plurality of separate regions where the plurality of chips are respectively connected; a holding step of holding the package substrate on a holding member in the condition where the sealing layer is in contact with the upper surface of the holding member; a groove forming step of cutting the redistribution layer along each division line by using groove forming means after performing the holding step to thereby form a groove having a first width, the groove having a depth dividing at least a ground line included in the redistribution layer; a contact metal filling step of filling the groove with a contact metal having conductivity both to the ground line and to a shield layer, after performing the groove forming step; a dividing step of cutting the contact metal and the sealing layer to a part of the holding member along the groove by using dividing means after performing the contact metal filling step, thereby forming a slit having a second width smaller than the first width of the groove to thereby divide the contact metal and divide the package substrate into individual semiconductor packages; and a shield layer forming step of depositing a conductive material to the sealing layer from the upper side thereof after performing the dividing step, thereby forming the shield layer on the side surface of each semiconductor package and the upper surface of the sealing layer.

According to the present invention, the contact metal is formed so as to cover the ground line exposed to the side surface of the redistribution layer. Accordingly, the ground line can be reliably connected through the contact metal to the shield layer formed on the side surface of the semiconductor package.

The above and other objects, features and advantages of the present invention and the manner of realizing them will become more apparent, and the invention itself will best be understood from a study of the following description and appended claims with reference to the attached drawings showing a preferred embodiment of the invention, while suppressing an increase in manufacturing cost.

### BRIEF DESCRIPTION OF THE DRAWINGS

FIG. 1 is a schematic sectional view of a semiconductor package according to a preferred embodiment of the present invention;

FIGS. 2A and 2B are schematic sectional views of semiconductor packages as different comparisons;

FIGS. 3A to 3C are schematic sectional views depicting a semiconductor package manufacturing method according to the preferred embodiment of the present invention;

FIGS. 4A to 4C are schematic sectional views depicting a semiconductor package manufacturing method according to the preferred embodiment of the present invention;

FIG. 5 is a schematic sectional view depicting a modification of the semiconductor package manufacturing method according to this preferred embodiment; and

FIG. 6 is a schematic sectional view depicting another modification of the semiconductor package manufacturing method according to this preferred embodiment.

### DETAILED DESCRIPTION OF THE PREFERRED EMBODIMENT

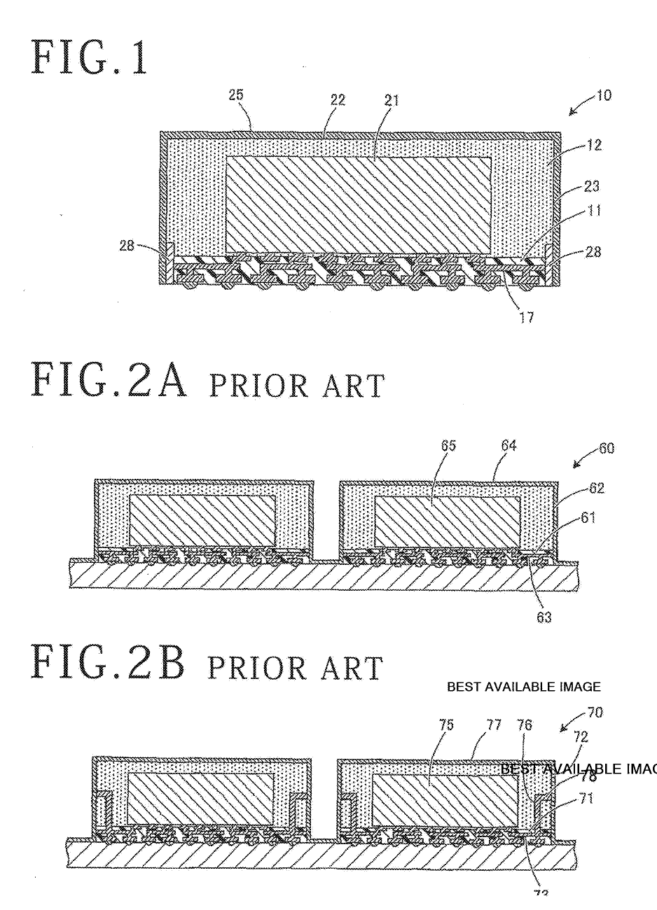

A semiconductor package manufacturing method according to a preferred embodiment of the present invention will now be described with reference to the attached drawings. FIG. 1 is a schematic sectional view of a semiconductor package to be manufactured according to this preferred embodiment. FIGS. 2A and 2B are sectional views of conventional semiconductor packages as different comparisons. The following preferred embodiment is merely illustrative, and another step may be added between steps. Further, the order of steps may be suitably changed.

Referring to FIG. 1, there is depicted a semiconductor package 10 according to this preferred embodiment. The semiconductor package 10 is a so-called fan-out wafer level package or the like such that a redistribution area is larger than a chip size. The semiconductor package 10 includes a redistribution layer 11 and a semiconductor chip 21 connected to the redistribution layer 11. The semiconductor chip 21 is sealed with a resin layer (sealing layer) 12. The semiconductor package 10 does not include a wiring substrate, but includes the redistribution layer 11 having a thickness of several micrometers to tens of micrometers. Accordingly, a wiring length is short and a transmission speed can therefore be increased. In addition, the thickness of the package can be reduced. Further, a manufacturing cost can be suppressed because no bonding wire is required.

The semiconductor chip 21 is previously formed by dividing a semiconductor wafer having a plurality of devices. The semiconductor package 10 including the semiconductor chip 21 has an upper surface 22 and a side surface 23. The upper surface 22 and the side surface 23 of the semiconductor package 10 are covered with a shield layer 25. The shield layer 25 is formed by sputtering or the like from the upper side of the semiconductor package 10. The side surface 23 of the semiconductor package 10 is a vertical surface. That is, the shield layer 25 is formed in the condition where adjacent semiconductor packages 10 are sufficiently spaced from each other, so that the shield layer 25 having a desired thickness can be formed. The shield layer 25 functions to suppress the leakage of electromagnetic noise from the semiconductor package 10.

Referring to FIG. 2A, a semiconductor package 60 is depicted as a comparison. The semiconductor package 60 has a side surface 62, which is covered with a shield layer 64. A redistribution layer 61 is included in the semiconductor package 60, and a ground line 63 is exposed to the side surface of the redistribution layer 61. The shield layer 64 is connected to the ground line 63 exposed to the side surface of the redistribution layer 61. However, since the thickness of the redistribution layer 61 is small, a contact failure is prone to occur between the ground line 63 in the redistribution layer 61 and the shield layer 64. In particular, when the semiconductor package 60 is picked up to cause film separation on the side surface 62 of the semiconductor package 60 as starting from a burr portion of the shield layer 64, the shield layer 64 may be separated from the ground line 63 exposed to the side surface of the redistribution layer 61, causing a contact failure.

Referring to FIG. 2B, a semiconductor package 70 is depicted as another comparison. The semiconductor package 70 has a side surface 72, which is covered with a shield layer 77. A redistribution layer 71 is included in the semiconductor package 70, and a ground line 73 is exposed to the side surface of the redistribution layer 71. In the configuration of the semiconductor package 70, a thick line 78 is drawn from the redistribution layer 71 to the side surface 72. Further, a post electrode 76 is provided on the redistribution layer 71 aside a semiconductor chip 75, and the thick line 78 is horizontally drawn from the upper end of the post electrode 76 to make a contact point with the shield layer 77 above the redistribution layer 71. Thus, a good contact between the ground line 73 and the shield layer 77 can be obtained through the post electrode 76 and the thick line 78. However, a photoresist step and an etching step are required to form the post electrode 76, causing an increase in number of steps and accordingly causing an increase in manufacturing cost.

To cope with the above problems, the semiconductor package 10 according to this preferred embodiment depicted in FIG. 1 includes a contact metal 28 provided on the side surface of the redistribution layer 11. A ground line 17 is exposed to the side surface of the redistribution layer 11, and this ground line 17 is connected through the contact metal 28 to the shield layer 25 covering the side surface 23 of the semiconductor package 10. With this configuration, a contact area between the contact metal 28 and the shield layer 25 is increased to thereby ensure a good contact and also improve the separation resistance of the shield layer 25. Furthermore, since the post electrode 76 as in the comparison depicted in FIG. 2B is not required, a photoresist step and an etching step are not required, so that an increase in number of steps can be minimized to thereby suppress an increase in manufacturing cost.

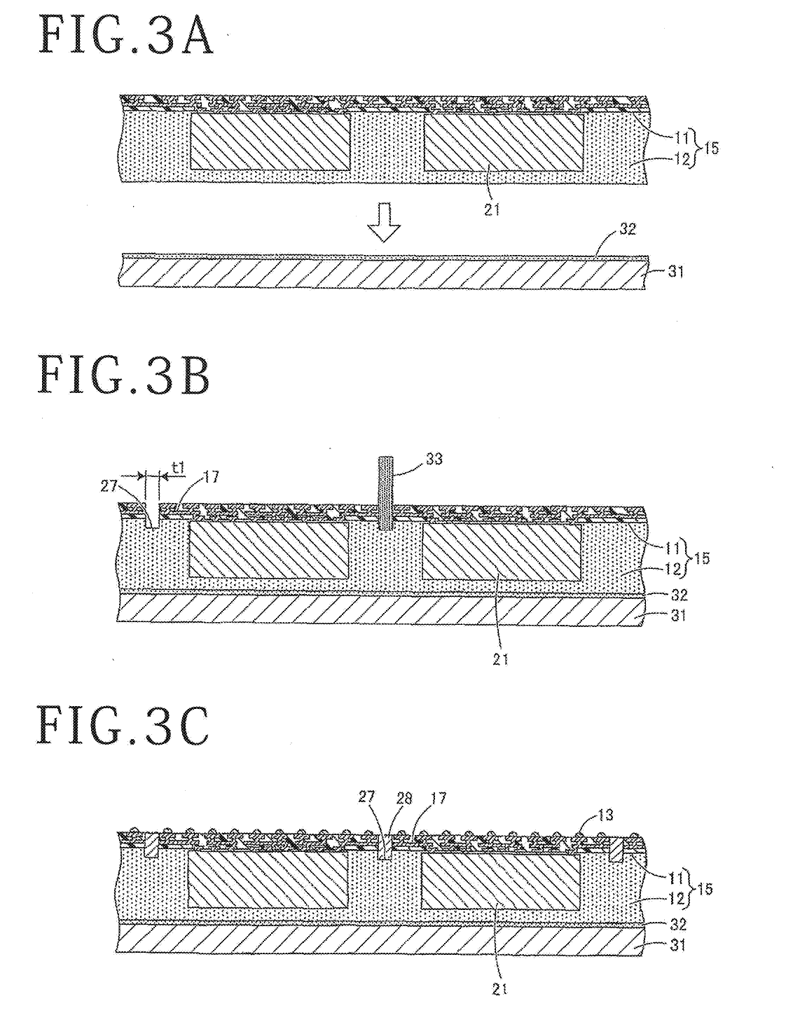

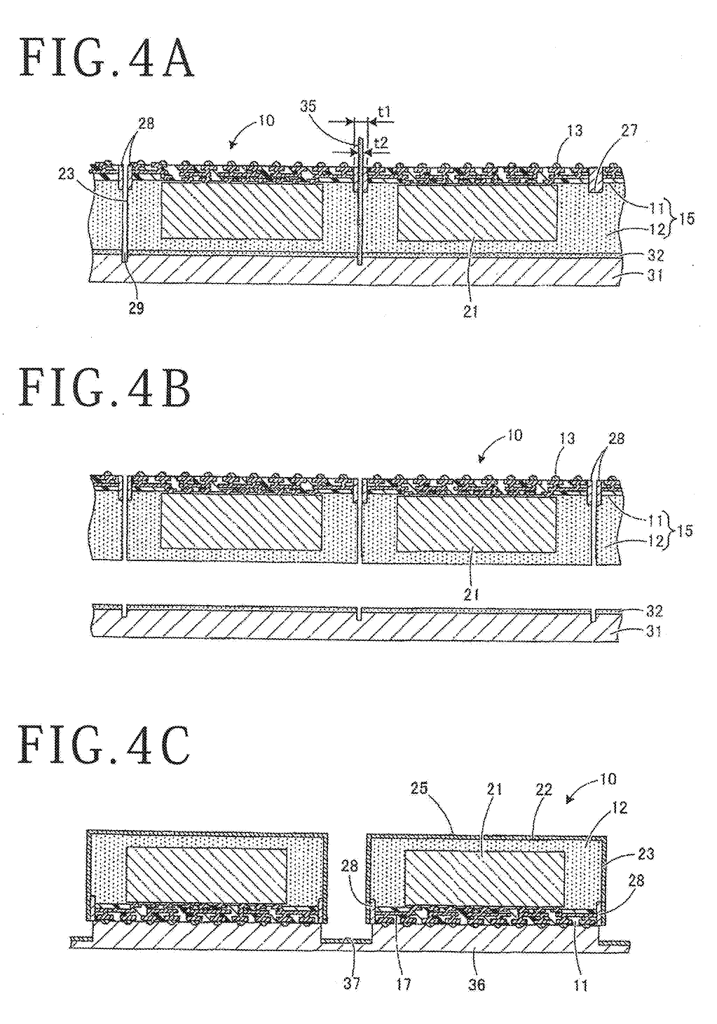

A semiconductor package manufacturing method according to this preferred embodiment will now be described with reference to FIGS. 3A to 4C. FIG. 3A depicts a holding step, FIG. 3B depicts a groove forming step, and FIG. 3C depicts a contact metal filling step. FIG. 4A depicts a dividing step, and FIGS. 4B and 4C depict a shield layer forming step.

As depicted in FIG. 3A, the holding step is first performed. In the holding step, a package substrate 15 is prepared. The package substrate 15 is previously formed by collectively sealing a plurality of semiconductor chips 21 with a sealing layer (resin layer 12). A redistribution layer 11 having a thickness of several micrometers to tens of micrometers is formed on the whole of one side of the package substrate 15. The redistribution layer 11 is partitioned by a plurality of crossing division lines (not depicted) to define a plurality of separate regions where the plural semiconductor chips 21 are respectively connected. The resin layer 12 of the package substrate 15 is attached through an adhesive layer 32 to a substrate 31 in the condition where the redistribution layer 11 is oriented upward.

The package substrate 15 may be formed by first sealing the semiconductor chips 21 with the resin layer 12 and next forming the redistribution layer 11 (chip—first method) or by first forming the redistribution layer 11 and next sealing the semiconductor chips 21 with the resin layer 12 (redistribution conductive layer (RDL)—first method). The adhesive layer 32 may be formed of any material capable of being reduced in adhesion by an external stimulus. Examples of the adhesive layer 32 include an ultraviolet curable resin, a heat peelable tape containing a foamed material in a dispersive condition, and a wax. The substrate 31 may be any member capable of holding the package substrate 15 in a flat condition. Examples of the substrate 31 include a silicon plate, a glass plate, and a metal plate. The sealing agent is selectable from any curable resins such as epoxy resin, silicone resin, urethane resin, unsaturated polyester resin, acrylic urethane resin, and polyimide resin.

As depicted in FIG. 3B, the groove forming step is performed after performing the holding step. In the groove forming step, a cutting blade 33 formed by binding diamond abrasive grains with a bond is mounted on a spindle (not depicted) at its front end. Further, the resin layer 12 of the package substrate 15 is held through the substrate 31 on a chuck table (not depicted). The cutting blade 33 is aligned with any predetermined one of the division lines at a horizontal position outside the package substrate 15. Thereafter, the cutting blade 33 is lowered to a vertical position corresponding to a predetermined depth where the redistribution layer 11 can be fully cut. Thereafter, the cutting blade 33 is rotated and the package substrate 15 is fed relative to the cutting blade 33, thereby cutting the package substrate 15 so as to fully cut the redistribution layer 11 along the predetermined division line. As a result, a groove 27 having a first width t1 is formed on the package substrate 15 along the predetermined division line so as to divide the redistribution layer 11.

Such a half cut of the package substrate 15 by the cutting blade 33 is repeated along all of the other division lines, so that a plurality of similar grooves 27 are formed on the package substrate 15 along all of the other division lines so as to divide the redistribution layer 11. By the formation of the grooves 27, the ground line 17 is exposed to the side surface of the redistribution layer 11 in each separate region. In the groove forming step, it is essential that the ground line 17 in the redistribution layer 11 can be cut by the cutting blade 33 along each division line. For example, the redistribution layer 11 may be partially cut to form a groove dividing the ground line 17. Alternatively, the redistribution layer 11 may be fully cut to form a groove having a depth reaching the resin layer 12.

As depicted in FIG. 3C, the contact metal filling step is performed after performing the groove forming step. In the contact metal filling step, each groove 27 is filled with a contact metal 28 having conductivity both to the ground line 17 and to a shield layer 25 (see FIG. 4C). Further, bumps 13 are formed on the redistribution layer 11. In this case, screen printing is performed to fill each groove 27 with the contact metal 28 and also form the bumps 13. In performing the screen printing, a screen mask having pattern holes is used and a solder paste is transferred through the pattern holes to the redistribution layer 11 of the package substrate 15.

The screen mask has the pattern holes for forming the bumps 13 and the pattern holes for filling the contact metal 28. Accordingly, the formation of the bumps 13 and the filling of the contact metal 28 are simultaneously performed by using the screen mask to transfer the solder paste. Prior to filling each groove 27 with the contact metal 28, a seed metal may be thinly deposited on the inside surface of each groove 27, so as to improve the adhesion between the ground line 17 and the contact metal 28. The contact metal 28 may be selected from any conductive metals, preferably any metals having a good contact property, separation resistance, and workability. For example, copper or metal compound may be used as the contact metal 28.

As depicted in FIG. 4A, the dividing step is performed after performing the contact metal filling step. In the dividing step, a thin cutting blade 35 formed by binding diamond abrasive grains with a bond is mounted on a spindle (not depicted) at its front end. Further, the resin layer 12 of the package substrate 15 is held through the substrate 31 on a chuck table (not depicted). The cutting blade 35 is aligned with any predetermined one of the grooves 27 filled with the contact metal 28 on the redistribution layer 11, at a horizontal position outside the package substrate 15. Thereafter, the cutting blade 35 is lowered to a vertical position corresponding to a predetermined depth where the contact metal 28 and the resin layer 12 can be fully cut and a part of the substrate 31 can also be cut. Thereafter, the cutting blade 35 is rotated and the package substrate 15 is fed relative to the cutting blade 35, thereby dividing the package substrate 15 along the predetermined groove 27 filled with the contact metal 28. As a result, a slit 29 having a second width t2 smaller than the first width t1 is formed through the package substrate 15 along the predetermined groove 27 filled with the contact metal 28. That is, the thickness of the cutting blade 35 corresponds to the second thickness t2 of the slit 29.

At this time, the slit 29 is formed in the condition where the center of the thickness of the cutting blade 35 coincides with the center of the first width t1 of the groove 27. Accordingly, the contact metal 28 filling the predetermined groove 27 is cut by the cutting blade 35 in the condition where laterally opposite parts of the contact metal 28 are left, and the package substrate 15 is divided along the predetermined groove 27 filled with the contact metal 28. Such division of the package substrate 15 by the cutting blade 35 is repeated along all of the other grooves 27 filled with the contact metal 28, so that the package substrate 15 is divided into individual semiconductor packages 10. In each semiconductor package 10, the ground line 17 exposed to the side surface of the redistribution layer 11 is covered with the contact metal 28, and the contact metal 28 is exposed to the side surface 23 of the semiconductor package 10.

As depicted in FIGS. 4B and 4C, the shield layer forming step is performed after performing the dividing step. As depicted in FIG. 4B, an external stimulus is applied to the adhesive layer 32 formed on the substrate 31 to thereby separate each semiconductor package 10 from the substrate 31. Thereafter, as depicted in FIG. 4C, each semiconductor package 10 is attached to a holding tape 36. The holding tape 36 has a holding surface formed with a plurality of crossing shallow grooves 37. That is, the holding surface of the holding tape 36 is partitioned by the crossing shallow grooves 37 to thereby define a plurality of separate regions. The redistribution layer 11 of each semiconductor package 10 is held on each separate region of the holding surface of the holding tape 36, and the semiconductor packages 10 are spaced from each other.

Thereafter, a conductive material is deposited to the semiconductor packages 10 from the upper side thereof, thereby forming a shield layer 25 on the upper surface 22 and the side surface 23 of each semiconductor package 10, i.e., on the exposed surface of each contact metal 28 and the exposed surface of each resin layer 12. The area of the contact metal 28 exposed to the side surface 23 of each semiconductor package 10 is large. Accordingly, even when the thickness of the ground line 17 in the redistribution layer 11 is small, the shield layer 25 on the side surface 23 can be well connected through the contact metal 28 to the ground line 17. With this configuration, the electromagnetic noise generated in each semiconductor package 10 can be removed through the ground line 17 and the contact metal 28 to the outside of each semiconductor package 10.

The width of each shallow groove 37 of the holding tape 36 is set larger than the spacing between the adjacent semiconductor packages 10, so that the side surface 23 of each semiconductor package 10 is so located as to overhang the side surface of each shallow groove 37. As a result, the shield layer 25 is not formed on the side surface of each shallow groove 37. That is, the shield layer 25 is divided by the side surface of each shallow groove 37 present between the side surface 23 of each semiconductor package 10 and the bottom surface of each shallow groove 37. Accordingly, the generation of burrs of the shield layer 25 in picking up each semiconductor package 10 can be suppressed to thereby prevent the film separation of the shield layer 25, so that a reduction in contact property between the shield layer 25 and the contact metal 28 can be prevented.

The shield layer 25 is a multilayer film having a thickness of several micrometers or more, and the multilayer film is formed by depositing one or more of copper, titanium, nickel, and gold, for example. This multilayer film may be formed by any method such as sputtering, ion plating, spray coating, CVD, ink jet printing, and screen printing. The shield layer 25 may be also formed by vacuum laminate such that a metal film having the above multilayer film is bonded to the upper surface 22 and the side surface 23 of each semiconductor package 10 under vacuum. In this manner, each semiconductor package 10 can be manufactured in the condition where the upper surface 22 and the side surface 23 are covered with the shield layer 25.

According to the manufacturing method for each semiconductor package 10 as described above, the contact metal 28 is formed so as to cover at least the ground line 17 exposed to the side surface of the redistribution layer 11 having a small thickness. Accordingly, a contact area between the contact metal 28 and the shield layer 25 can be increased to thereby ensure the connection between the ground line 17 and the shield layer 25 on the side surface 23 of each semiconductor package 10. Further, with the simple configuration that the contact metal 28 is formed on the side surface of the redistribution layer 11, an increase in cost can be suppressed as compared with the conventional configuration that a post electrode is formed in each package.

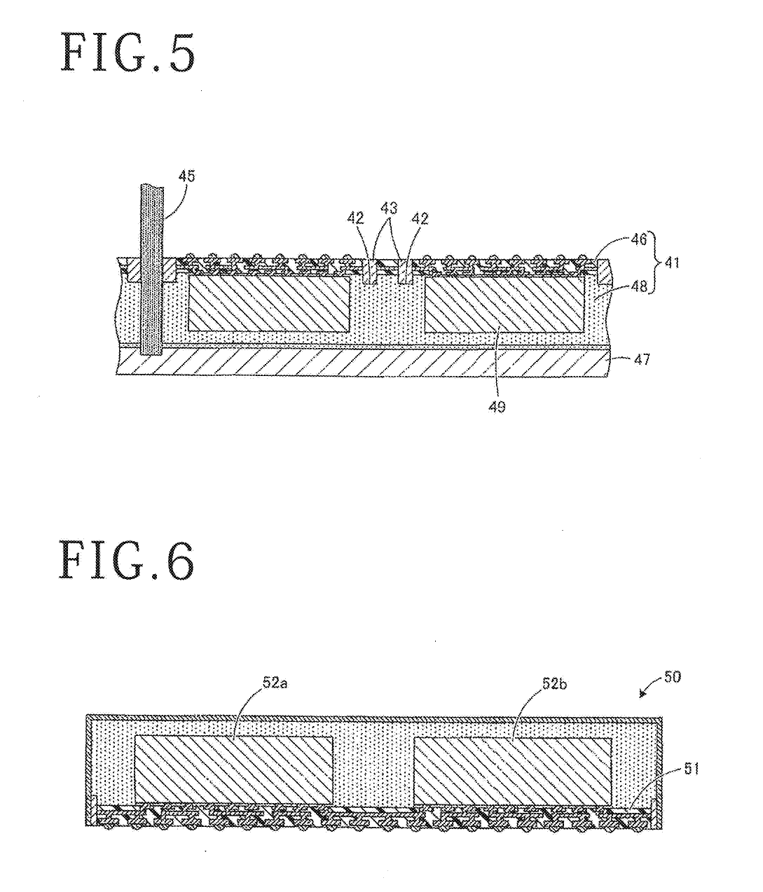

In the above preferred embodiment, the groove 27 is formed on the redistribution layer 11 along each division line, and this groove 27 is then filled with the contact metal 28. Thereafter, the contact metal 28 is cut by using the cutting blade 35. This method is merely illustrative, and another method depicted in FIG. 5 may be adopted as a modification in the case that a contact metal 43 is low in workability. As depicted in FIG. 5, two parallel grooves 42 are formed on a redistribution layer 46 along each division line (inside the width of each division line). Thereafter, each groove 42 is filled with the contact metal 43. Thereafter, the redistribution layer 46 between the two grooves 42 filled with the contact metal 43 is cut by using a cutting blade 45. In this groove forming step, the two grooves 42 are formed in symmetry with respect to the lateral center of each division line (the center of the width of each division line). Thereafter, in the contact metal filling step, each groove 42 is filled with the contact metal 43.

In the dividing step, the cutting blade 45 is used to cut a package substrate 41. The cutting blade 45 has a thickness slightly larger than the spacing between the two parallel grooves 42. Accordingly, the redistribution layer 46 between the two grooves 42 filled with the contact metal 43 is fully cut by the cutting blade 45, and a resin layer 48 of the package substrate 41 is also fully cut by the cutting blade 45 until a substrate 47 attached to the lower surface of the package substrate 41 is partially cut by the cutting blade 45. Accordingly, even when the contact metal 43 is low in workability, the amount of the contact metal 43 to be cut by the cutting blade 45 can be suppressed to thereby prevent a reduction in cutting performance of the cutting blade 45 such as dulling. Further, since the thickness of the contact metal 43 is larger, the contact property can be improved.

In the above preferred embodiment, the single semiconductor chip 21 is connected to the redistribution layer 11 in each semiconductor package 10. This configuration is merely illustrative, and a semiconductor package including a plurality of semiconductor chips mounted on a redistribution layer may be manufactured by the present invention. Such a configuration is depicted in FIG. 6 as another modification. As depicted in FIG. 6, a plurality of (e.g., two) semiconductor chips 52a and 52b are connected to a redistribution layer 51, and these semiconductor chips 52a and 52b are collectively sealed to manufacture a semiconductor package 50. The semiconductor chips 52a and 52b may have the same function or may have different functions.

While the cutting blade 33 is used as groove forming means in the groove forming step of the manufacturing method according to the above preferred embodiment, the groove forming means is not limited in the present invention, provided that the groove forming means can form the groove having the first width t1 for dividing at least the ground line of the redistribution layer. For example, a profiler may be used as the groove forming means to form the groove on the package substrate. Further, a processing head for laser ablation may be used as the groove forming means to perform laser ablation on the package substrate, thereby forming the groove on the package substrate. The laser ablation mentioned above means a phenomenon such that when the intensity of a laser beam applied becomes equal to or greater than a predetermined processing threshold, the energy of the laser beam is converted into electronic, thermal, photochemical, and mechanical energy on the surface of a solid, so that neutral atoms, molecules, positive and negative ions, radicals, clusters, electrons, and light are explosively emitted and the solid surface is accordingly etched.

Further, while the cutting blade 35 is used as dividing means in the dividing step of the manufacturing method according to the above preferred embodiment, the dividing means is not limited in the present invention, provided that the dividing means can form the slit having the second width t2 smaller than the first width t1 through the thickness of the package substrate. For example, a profiler may be used as the dividing means to divide the package substrate. Further, a processing head for laser ablation may be used to perform laser ablation, thereby dividing the package substrate. Further, the groove forming step and the dividing step may be performed by using the same apparatus or by using different apparatuses.

Further, while the groove formed through the redistribution layer is filled with the contact metal by screen printing in the contact metal filling step of the manufacturing method according to the above preferred embodiment, the present invention is not limited to this configuration, provided that the groove formed through the redistribution layer can be filled with the contact metal. For example, a dispenser may be used to fill the groove with the contact metal.

Further, while the substrate is used as a holding member in the holding step of the manufacturing method according to the above preferred embodiment, the holding member is not limited in the present invention, provided that the holding member can hold the package substrate. For example, a holding tape, holding jig, or chuck table may be used as the holding member.

Further, while the shield layer is formed in the condition where the semiconductor packages are held on the holding tape having the shallow grooves in the shield layer forming step of the manufacturing method according to the above preferred embodiment, the present invention is not limited to this configuration. For example, the shield layer may be formed in the condition where the semiconductor packages are held on a holding jig having shallow grooves. Further, in the case that the film separation of the shield layer does not become a problem, the shallow grooves may not be formed on the holding tape or the holding jig.

Further, while the semiconductor package in the above preferred embodiment is a fan-out wafer level package, the present invention is not limited to this configuration. The present invention is applicable also to a manufacturing method for any other types of semiconductor packages.

Further, while the semiconductor chip as a chip is connected to the redistribution layer in the above preferred embodiment, the chip is not limited in the present invention, provided that the chip may be a chip component mounted on a redistribution layer. For example, the chip may be a capacitor or any other chip components.

Further, the semiconductor package may be applied not only to portable communications equipment such as mobile phones, but also to any other electronic equipment such as cameras.

Further, the above preferred embodiment and various modifications may be combined generally or partially to perform other preferred embodiments.

Further, the present invention is not limited to the above preferred embodiment and modifications mentioned above, but various modifications, replacements, and changes may be made within the scope of the present invention. Further, if the technical idea of the present invention can be realized by any other methods using any technical progress or derivative techniques, the present invention may be embodied by using these methods. Accordingly, the present invention claimed herein is intended to cover all embodiments that may fall within the scope of the present invention.

Further, while the present invention is applied to a semiconductor package manufacturing method in the above preferred embodiment, the present invention is applicable also to a manufacturing method for any other package components in which a redistribution layer is formed.

As described above, the present invention has an effect that the ground line in the redistribution layer can be brought into reliable contact with the shield layer formed on the side surface of the semiconductor package without an increase in cost. In particular, the present invention is useful as a semiconductor package to be used in portable communications equipment and also useful as a manufacturing method for such a semiconductor package.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A semiconductor package including a redistribution layer and a chip connected to said redistribution layer, said chip being sealed with a sealing layer, said redistribution layer including a ground line exposed to a side surface of said redistribution layer, said semiconductor package comprising:
a contact metal formed on a side surface of said redistribution layer so as to cover at least said ground line; and
a shield layer formed on an exposed surface of said contact metal and an exposed surface of said sealing layer,
said shield layer being connected through said contact metal to said ground line exposed to the side surface of said redistribution layer.

2. A semiconductor package manufacturing method comprising:
a preparing step of preparing a package substrate formed by collectively sealing a plurality of chips with a sealing layer, said package substrate including a redistribution layer partitioned by a plurality of crossing division lines to define a plurality of separate regions where said plurality of chips are respectively connected;
a holding step of holding said package substrate on a holding member in a condition where said sealing layer is in contact with an upper surface of said holding member;
a groove forming step of cutting said redistribution layer along each division line by using groove forming means after performing said holding step to thereby form a groove having a first width, said groove having a depth dividing at least a ground line included in said redistribution layer;
a contact metal filling step of filling said groove with a contact metal having conductivity both to said ground line and to a shield layer, after performing said groove forming step;
a dividing step of cutting said contact metal and said sealing layer to a part of said holding member along said groove by using dividing means after performing said contact metal filling step, thereby forming a slit having a second width smaller than said first width of said groove to thereby divide said contact metal and divide said package substrate into individual semiconductor packages; and
a shield layer forming step of depositing a conductive material to said sealing layer from the upper side thereof after performing said dividing step, thereby forming said shield layer on the side surface of each semiconductor package and the upper surface of said sealing layer.
